(19) United States
(12) Patent Application Publication
(10) Pub. No.: US 2026/0212515 A1
(43) Pub. Date: Jul. 23, 2026

(54) METHOD FOR REGISTERING STRUCTURES IN AN IMAGE OF A PHOTOLITHOGRAPHY MASK TO CORRESPONDING STRUCTURES IN A REFERENCE IMAGE AND CORRESPONDING SYSTEM

(71) Applicant: Carl Zeiss SMT GmbH, Oberkochen (DE)

(72) Inventors: Niklas Georg, Haiger (DE); Martin van Driel, Muenchen (DE); Maximilian Bemmann, Leipzig (DE); Susanne Toepfer, Gleina / OT Baumersroda (DE)

(21) Appl. No.: 19/453,259

(22) Filed: Jan. 20, 2026

(30) Foreign Application Priority Data
Jan. 22, 2025 (DE) 102025102252.6

(51) Int. Cl. G06T 7/32; G03F 1/84; G06T 5/70; G06T 7/00

(52) U.S. Cl. CPC G06T 7/32; G03F 1/84; G06T 5/70; G06T 7/001; G06T 2207/30148

(57) ABSTRACT

The invention relates to a method for registering structures in an image of a photolithography mask comprising: providing an image of a photolithography mask acquired by an optical system, wherein the noise distribution of the image varies depending on at least one property of the image, the photolithography mask or the optical system; and registering structures in a transformation of the image to corresponding structures in a reference image of the photolithography mask, wherein the variation of the noise distribution is reduced in the transformed image.

### CROSS-REFERENCE TO RELATED APPLICATION

This application claims benefit of German patent application 10 2025 102 252.6, filed on Jan. 22, 2025, which is hereby incorporated by reference in its entirety.

### TECHNICAL FIELD

The invention relates to methods and corresponding systems for registering structures in an image of a photolithography mask obtained by an optical system, e.g., in an optical metrology system or an optical inspection system. The registered structures can be used for evaluating the quality of a photolithography mask, for example, for measuring positions of structures on the photolithography mask, or for detecting defects in the photolithography mask.

### BACKGROUND

Semiconductor manufacturing involves precise manipulation, e.g., etching, of materials such as silicon or oxide at very fine scales in the range of nm. A wafer made of a thin slice of silicon serves as the substrate for microelectronic devices containing semiconductor structures built in and upon the wafer. The semiconductor structures are constructed layer by layer using repeated processing steps that involve repeated chemical, mechanical, thermal and optical processes. Photolithography is a process used to produce patterns on the substrate. The patterns to be printed on the surface of the substrate are generated by computer-aided-design (CAD). From the design, for each layer a photolithography mask is generated, which contains a magnified image of the computer-generated pattern to be etched into the substrate. The photolithography mask can be further adapted, e.g., by use of optical proximity correction techniques. During the printing process an illuminated image projected from the photolithography mask is focused onto a photoresist thin film formed on the substrate. A semiconductor chip powering mobile phones or tablets comprises, for example, approximately between 80 and 120 patterned layers.

Due to the growing integration density in the semiconductor industry, photolithography masks have to image increasingly smaller structures onto wafers. The aspect ratio and the number of layers of integrated circuits constantly increases and the structures are growing into 3^{rd} (vertical) dimension. The current height of the memory stacks is exceeding a dozen of microns. In contrast, the feature size is becoming smaller. The minimum feature size or critical dimension is below 10 nm, for example 7 nm or 5 nm, and is approaching feature sizes below 3 nm in near future. While the complexity and dimensions of the semiconductor structures are growing into the 3^{rd} dimension, the lateral dimensions of integrated semiconductor structures are becoming smaller. Producing the small structure dimensions imaged onto the wafer requires photolithographic masks or templates for nanoimprint photolithography with ever smaller structures or pattern elements. The production process of photolithographic masks and templates for nanoimprint photolithography is, therefore, becoming increasingly more complex and, as a result, more time-consuming and ultimately also more expensive. With the advent of EUV photolithography scanners, the nature of masks changed from transmission-based to reflection-based patterning.

On account of the tiny structure sizes of the pattern elements of photolithographic masks, it is not possible to exclude errors during mask production. The resulting defects can, for example, arise from degeneration of photolithography masks or particle contamination. Hence, in semiconductor process control, photolithography mask inspection, review, and metrology play a crucial role to monitor systematic defects. Defects detected during quality assurance processes can be used for root cause analysis, for example, to modify, repair or even discard the photolithography mask.

Optical systems examine structures on photolithography masks using images. An image is formed by the projection of light, e.g., of EUV or DUV wavelength, through a photolithography mask onto an imaging sensor, e.g., charge coupled device (CCD) or complementary metal oxide semiconductor (CMOS) arrays. The image, thus, represents the distribution of light on the surface of a wafer. By registering structures in the image with corresponding structures in a reference image, positions of structures can be measured and defects can be detected on the photolithography mask. However, the accuracy of all such measurements is negatively influenced by noise in the acquired image. Noise refers to random variations of the brightness in the image. Optical images are predominantly affected by shot noise that is due to the particle nature of light. The shot noise in the image depends on the image intensity. The higher the intensity in the image, the higher the noise level. Further noise types such as Gaussian noise can also occur in the image. Registration algorithms are usually based on the assumption of identically distributed noise in the image, in particular identically distributed Gaussian noise. As images obtained by an optical system do not follow this assumption due to the predominant shot noise, the accuracy of the registration of the image and the reference image is reduced.

It is, therefore, an aspect of the invention to increase the accuracy of the registration of an image obtained by an optical system and a reference image. Further, it is an aspect of the invention to increase the accuracy of quality evaluations of the photolithography mask.

The aspects are achieved by the invention specified in the independent claims. Advantageous embodiments and further developments of the invention are specified in the dependent claims.

### SUMMARY

Embodiments of the invention concern methods and corresponding systems for registering structures in an image of a photolithography mask obtained by an optical system to corresponding structures in a reference image.

A first embodiment involves a method for registering structures in an image of a photolithography mask, the method comprising: providing an image of a photolithography mask acquired by an optical system, wherein the noise distribution of the image varies depending on at least one property of the image, the photolithography mask or the optical system; and registering structures in a transformation of the image to corresponding structures in a reference image of the photolithography mask, wherein the variation of the noise distribution is reduced in the transformed image. The method can be implemented on a computer.

The noise distribution varies with a property of the image, the photolithography mask or the optical system, e.g., with image intensity, image location, photolithography mask material or with the sensor of the optical system, etc. This means that the noise is not identically distributed in the image, but that the type or parameters of the noise distribution depend on this property. For example, in case of shot noise the noise is Poisson distributed, such that its variance depends on the image intensity. By using the image transformation the variation of the noise distribution is reduced in the transformed image. Thus, the noise distribution becomes more homogeneous and closer to identically distributed. In case of shot noise, the variance of the noise distribution depends less on the image intensity. The variation of the noise distribution can, for example, be measured by computing the variance of the variance or some other statistical property of the noise distribution over the image. Depending on the specific image transformation, the noise distribution of the transformed image can be approximately a Gaussian distribution. In this way, the assumption of an identically distributed noise distribution, in particular a Gaussian noise distribution, that is usually implicitly made by standard registration methods is better fulfilled. Thus, the accuracy of the registration is improved.

According to an example, the noise distribution of the image comprises a Poisson distributed component and/or a Gaussian distributed component. Poisson distributed shot noise is usually the dominant source of noise in optical images and depends on the image intensity. Therefore, this form of noise does not fulfill the assumption of an identically distributed noise distribution or a Gaussian noise distribution in standard registration methods.

In an example, the noise distribution of the image varies depending on at least one property of the image, the photolithography mask or the optical system from the group comprising: image intensity, image location, image contents, photolithography mask material, photolithography mask structure type, detector properties of the optical system. Such varying noise distributions lead non-identically distributed noise and, thus, to inaccurate registration results.

In an example, the variance of the noise distribution of the image varies depending on the at least one property of the image, and the variation of the variance of the noise distribution is reduced in the transformed image. By reducing the variation of the noise distribution, the noise distribution becomes more homogeneous and, thus, closer to identically distributed in the image. Thus, the assumptions of identically distributed noise in the image is better fulfilled and the registration accuracy improved.

According to an aspect of the invention, the variance of the noise distribution of the transformed image is approximately constant. In particular, the noise distribution of the transformed image approximately follows an identically distributed Gaussian distribution. Such noise distributions fulfill the assumptions of standard registration algorithms and lead to an improved registration accuracy.

According to a preferred example, the transformation of the image comprises a variance stabilizing transformation. A variance stabilizing transformation reduces the variation of the variance of the noise distribution in the image. An Anscombe transform can be used to transform a Poisson noise distribution into a Gaussian distribution, wherein the variance is independent of the mean and, thus, the noise variance independent of the image intensity. A generalized Anscombe transform can be used to transform a Poisson noise distribution with an additional Gaussian noise component into a Gaussian distribution. In this way, the registration accuracy is improved.

According to an example, the variance stabilizing transformation is obtained by solving an optimization problem that minimizes the deviation of an estimated noise variance in the image from a constant noise variance. In this way, the variance stabilizing transformation can be tailored to the exact noise distribution in the image to achieve an increased registration accuracy.

According to an aspect, the image comprises at least two subimages, each with a different noise distribution, and the variation of the noise distribution is reduced within each subimage of the image. By transforming each subimage separately, the image transform for each subimage can be specifically tailored to the noise distribution within the subimage to achieve a higher registration accuracy.

In an example, a pixelwise confidence score is estimated from the noise distribution of the image, and the confidence score is used as a weighting factor when registering structures in the transformed image to corresponding structures in the reference image. In this way, less noisy portions of the image influence the registration result more than more noisy portions of the image. This leads to an increased registration accuracy.

In an example, parameters of the noise distribution of the image (and, thus, parameters of the image transformation) are estimated from one or more images obtained by the optical system and/or from the optical system itself. In this way, the image transformation is particularly tailored to the noise distribution in the image and/or to the optical system. The more images are used for the parameter estimation the higher the accuracy of the estimated parameters and the registration.

According to a preferred example, the transformation of the image further comprises filtering the image using a filter that depends on the shape of an imaging pupil of the optical system. In this way, pure noise frequencies are filtered from the image to improve the registration accuracy.

In an example, a transformation is applied to the reference image that reduces the variation of the noise distribution in the reference image. In this way, the variation of the noise distribution is also reduced in the reference image to further improve the registration accuracy.

According to an example, the method further comprises evaluating the quality of the photolithography mask from registered structures in the image and the reference image. The registered structures can be used to measure positions of structures on the photolithography mask (metrology system) or to detect defects in the photolithography mask (inspection system). From this information, conclusions can be drawn on the quality of the photolithography mask.

In an example, the optical system is an optical metrology system that measures positions of structures in the photolithography mask from registered structures in the image and the reference image.

In an example, the optical system is an optical inspection system that detects defects in the photolithography mask by comparing registered structures in the image and the reference image.

In an example, the method further comprises controlling at least one photolithography mask manufacturing process parameter based on the quality evaluation of the photolithography mask.

A system for registering structures in an image of a photolithography mask obtained by an optical system comprises: an optical system for acquiring an image of a photolithography mask; one or more processing devices; one or more machine-readable hardware storage devices comprising instructions that are executable by one or more processing devices to perform operations comprising a method for registering structures in an image of a photolithography mask according to any one of the embodiments, examples or aspects of the invention described above.

The invention described by examples and embodiments is not limited to the embodiments and examples but can be implemented by those skilled in the art by various combinations or modifications thereof.

### BRIEF DESCRIPTION OF DRAWINGS

FIG. 1 illustrates an exemplary transmission-based optical system, e.g., a deep ultraviolet (DUV) optical system;

FIG. 2 illustrates an exemplary reflection-based optical system, e.g., an extreme ultra-violet light (EUV) optical system;

FIGS. 3A and 3B show an image comprising shot noise and an estimated noise distribution;

FIG. 4 illustrates a flowchart of a method for registering structures in an image of a photolithography mask according to an embodiment of the invention;

FIGS. 5A-5D illustrate the application of a transformation to the image that reduces the variation of the noise distribution in the image;

FIG. 6 illustrates the estimation of parameters of the noise distribution in the image from one or more acquired images of the optical system;

FIG. 7 illustrates the application of the method according to the invention to separate subimages of the image with different noise distributions;

FIG. 8 shows the generation of a confidence score from the noise distribution in the image, wherein the confidence score is used as a weighting factor during registration;

FIGS. 9A and 9B show the derivation of an NA filter that depends on the shape of an imaging pupil of the optical system and filters noise frequencies from the image;

FIGS. 10A-10D show reproducibility results for registrations of repeatedly acquired images of the optical system for raw image data compared to generalized Anscombe transformed image data;

FIGS. 11A-11F show error distributions of simulated registration results for different preprocessing methods;

FIGS. 12A and 12B show corresponding structures in a reference image and an image that are registered to measure positions of structures on a photolithography mask in an optical metrology system;

FIGS. 13A-13C show structures in a reference image and corresponding structures in an image that are registered to detect defects on the photolithography mask in an optical inspection system; and

FIG. 14 shows a system for registering structures in an image of a photolithography mask obtained by an optical system according to an embodiment of the invention.

### DETAILED DESCRIPTION

In the following, advantageous exemplary embodiments of the invention are described and schematically shown in the figures. Throughout the figures and the description, same reference numbers are used to describe same features or components. Dashed lines indicate optional features.

The optical systems herein can use illumination light of different wavelengths, e.g., transmission-based optical systems 10 or reflection-based optical systems 10′ such as EUV systems.

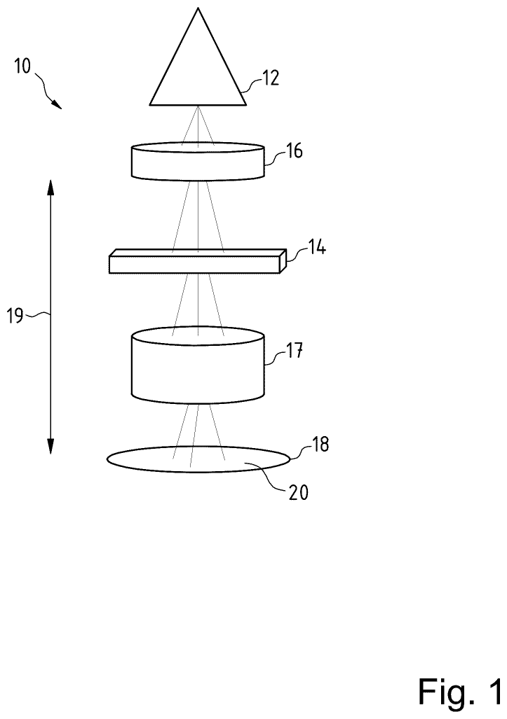

FIG. 1 illustrates an exemplary transmission-based optical system 10 for measuring structures on photolithography masks using DUV light. Major components are a light source 12, which may be a deep-ultraviolet (DUV) excimer laser source, imaging optics which, for example, define the partial coherence and which may include optics that shape radiation from the light source 12, a photolithography mask 14, illumination optics 16 that illuminate the photolithography mask 14 and projection optics 17 that project an image of the photolithography mask onto a wafer plane 18. An adjustable filter or aperture at the pupil plane of the projection optics 17 may restrict the range of beam angles that impinge on the wafer plane 18, where the largest possible angle defines the numerical aperture of the projection optics NA=n sin(θₘₐₓ), wherein n is the refractive index of the media between the substrate and the last element of the projection optics 17, and θₘₐₓ is the largest angle of the beam exiting from the projection optics 17 that can still impinge on the wafer plane 18. The radiation distribution at the wafer plane 18 is imaged by an image sensor 20 of a camera, e.g., a CCD or CMOS sensor, to generate an image that is used for measuring tasks.

In the present document, the terms “illumination”, “radiation” or “beam” are used to encompass all types of electromagnetic radiation, including ultraviolet radiation (e.g., with a wavelength of 365, 248, 193, 157 or 126 nm) and EUV (extreme ultra-violet radiation, e.g., having a wavelength in the range of about 3-100 nm).

Illumination optics 16 may include optical components for shaping, adjusting and/or projecting radiation from the light source 12 before the radiation passes the photolithography mask 14. Projection optics 17 may include optical components for shaping, adjusting and/or projecting the radiation after the radiation passes the photolithography mask 14. The illumination optics 16 exclude the light source 12, the projection optics exclude the photolithography mask 14.

Illumination optics 16 and projection optics 17 may comprise various types of optics, including refractive optics, reflective optics, apertures and catadioptric optics, for example. Illumination optics 16 and projection optics 17 may also include components operating according to any of these design types for directing, shaping or controlling the projection beam of radiation, collectively or singularly.

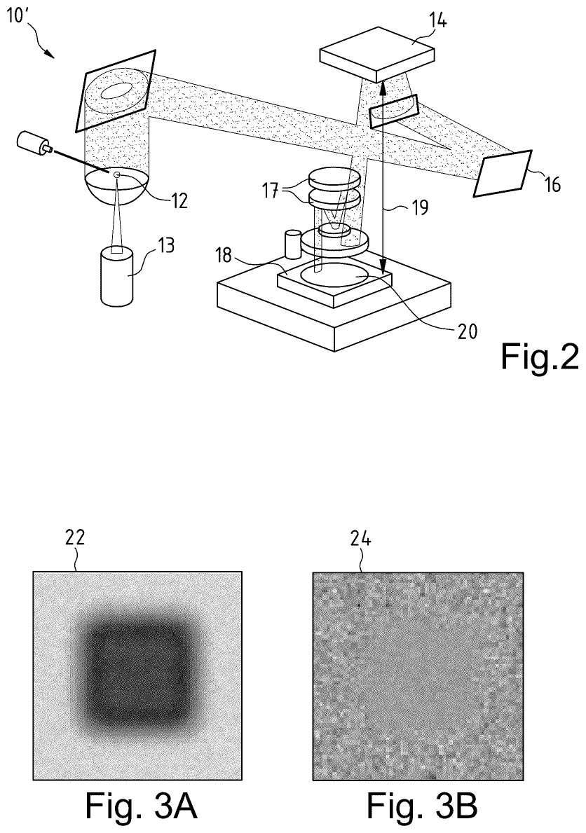

FIG. 2 illustrates an exemplary reflection-based optical system 10′ for measuring structures on photolithography masks using extreme ultraviolet (EUV) light. Major components are a light source 12 in the form of an EUV plasma source that is ignited by an IR-laser 13, illumination optics 16 which, for example, define the partial coherence and which may include optics that shape radiation from the light source 12, a photolithography mask 14, and projection optics 17 that project an image of the photolithography mask onto a wafer plane 18. An adjustable filter or aperture at the pupil plane of the projection optics 17 may restrict the range of beam angles that impinge on the wafer plane 18, where the largest possible angle defines the numerical aperture of the projection optics NA=n sin(θₘₐₓ), wherein n is the refractive index of the media between the substrate and the last element of the projection optics 17, and θₘₐₓ is the largest angle of the beam exiting from the projection optics 17 that can still impinge on the wafer plane 18. The radiation distribution at the wafer plane 18 is imaged by an image sensor 20 of a camera to generate an image.

An optical system 10, 10′ such as the ones shown in FIGS. 1 and 2 can be used to generate an image of the photolithography mask that is used for registering structures in an image of a photolithography mask to corresponding structures in a reference image of the photolithography mask.

An optical system refers to a system that uses light to obtain an image of a photolithography mask. It illuminates the photolithography mask with light from an illumination source and projects the reflected or transmitted light from the photolithography mask surface to a camera sensor array. Optical systems comprise, for example, optical inspection systems, optical mask qualification systems, and optical metrology systems.

An optical inspection system refers to an optical system used to detect defects in a photolithography mask by acquiring and analyzing aerial images of the photolithography mask or one or more sections thereof. In particular, inspection systems comprise actinic photomask inspection systems

An optical mask qualification system refers to a system that is used to acquire an image of a portion of a photolithography mask, thereby emulating settings of a photolithography system, e.g., illumination and imaging parameters. The acquired image is of a higher quality than an image acquired by an optical inspection system, e.g., of a reduced noise level. The portions of the photolithography mask can comprise potential defect locations detected using an optical inspection system for further review. The acquired image can be used to examine the effect of a potential defect on a printed wafer, to verify that photolithography masks are defect-free, whether a repair attempt has been successful or for critical dimension estimation.

An optical metrology system refers to a system that is used to take measurements of structures in a photolithography mask by acquiring an image of the photolithography mask.

The photolithography mask may have an aspect ratio of between 1:1 and 1:4, preferably between 1:1 and 1:2, most preferably of 1:1 or 1:2. The photolithography mask may have a nearly rectangular shape. The photolithography mask may be preferably 5 to 7 inches long and wide, most preferably 6 inches long and wide. Alternatively, the photolithography mask may be 5 to 7 inches long and 10 to 14 inches wide, preferably 6 inches long and 12 inches wide.

A structure in an image refers to the image of a component of the photolithography mask, e.g., absorber structures, channels, contact structures, word lines, deck transitions, bit lines, source lines, gates, etc.

An image of a photolithography mask can refer to different kinds of images of the photolithography mask, e.g., to a two-dimensional image, a three-dimensional image, a stack of images or a volumetric three-dimensional image that can, for example, be processed slice by slice. An image can be an image of a complete photolithography mask or of a section of the photolithography mask.

According to an example, an image refers to an aerial image. An aerial image indicates the radiation intensity distribution of an optical system in a wafer plane for a given photolithography mask. It refers to the image that is formed by the projection of light, e.g. of EUV or DUV wavelength, through a photolithography mask onto an imaging sensor, e.g. CCD or CMOS arrays. The aerial image, thus, simulates the structures on the surface of a wafer after printing. A wafer plane refers to a plane within the resist on top of the wafer. The imaging sensor can be part of a camera adapted for acquiring images at predetermined wavelengths. The camera can be an EUV camera, and/or a camera comprising a time delay integration (TDI) sensor. In preferred embodiments, an image acquisition method comprises the use of an EUV camera comprising a TDI sensor. The camera's image sensor can accordingly be an EUV image sensor, i.e., an image sensor that is sensitive to EUV light. EUV light is light in the extreme ultraviolet spectral range with wavelengths between 5 nm and 100 nm, in particular with wavelengths between 5 nm and 30 nm. Especially the EUV light can have a wavelength of 13.5 nm. In preferred embodiments, the image acquisition method comprises illuminating a photolithography mask with actinic radiation within the EUV wavelength range. EUV radiation reflected from the mask is then projected on an imaging sensor of an EUV camera via accordingly adapted projection optics.

A reference image refers to an image of a photolithography mask or of a section thereof, that represents (at least approximately) the same structures as the image of the photolithography mask. The reference image can be of the same type as the image or of a different type such as a SEM image or a design image. A reference image can comprise an acquired image of the same photolithography mask, e.g., at a different point in time, using a different optical system, using the same optical system with different settings, using a different section of the same photolithography mask that contains the same structures, etc. An image can also be used as a reference image for itself, e.g., a mirrored image can be used as a reference image in case the image contains structures that are self-symmetrical. A reference image can comprise an acquired image of a different photolithography mask comprising the same structures as the image of the photolithography mask using the same or a different optical system. A reference image can also comprise a simulated image. An image can be simulated from a model of a photolithography mask using image simulation methods. For example, rigorous simulation methods such as finite difference time domain (FDTD) or rigorous coupled wave analysis (RCWA) can be used that are known to a person skilled in the art. Since they require long computation times, fast but less accurate approximations such as the thin element approximation (TEA) that relies on a thin mask assumption can be used. To obtain fast and accurate results, simulation methods that are based on physical models but still do not rely on the thin mask assumption can be used, e.g., the not quite rigorous method disclosed in WO 2024 141484 A1 and in DE 2022 135 019 A1. Apart from physical simulations, trained machine learning models can be used to simulate images from designs. A reference image can also comprise a model of the photolithography mask, e.g., a design file or some other representation of the structures on the photolithography mask. The appearance of the model of the photolithography mask can be adapted to look like an acquired image of the photolithography mask, e.g., using simulation software or machine learning models for appearance modification such as generative adversarial models or conditional generative adversarial models.

A model (or design) of a photolithography mask refers to a representation of the photolithography mask or a section thereof. The model can, for example, comprise a computer readable file, such as a CAD file or a GDS file, or a technical drawing, a set of polygons representing the structures of the photolithography mask or a section thereof. A model of a photolithography mask can comprise parameters describing the location of structures in the photolithography mask, e.g., the location of absorber structures or layers in a multilayer. A model of a photolithography mask can comprise parameters describing the shape of structures in the photolithography mask, e.g., the shape of the absorber structures such as side wall angles or corner rounding, etc. A model of a photolithography mask can comprise descriptions of the structures within the photolithography mask, e.g., in the form of curves, contours, polygons, Splines, NURBS, Bézier curves, etc. A model of a photolithography mask can comprise material information, e.g., complex refractive indices of materials contained in the photolithography mask, electric permittivities, magnetic permeabilities, or derived representations. A model of a photolithography mask can comprise parameters describing dimensions of structures in the photolithography mask, e.g., the thicknesses of the layers in the multilayer of an EUV mask or the thickness of absorber layers, or the dimension of the absorber structures. A model of a photolithography mask can comprise an image, e.g., a 2D image or a 3D image (e.g., a volume of voxels or a number of 2D slices of a volume), that represents properties of the photolithography mask. The image can contain one, two or more channels. The image can comprise image elements, e.g., pixels or voxels. A model can refer to the model of a complete photolithography mask, or it can refer to the model of a section of the photolithography mask.

In an example, a transformation is applied to the reference image that reduces the variation of the noise distribution in the reference image. For example, if the reference image is the image itself or another section of the image of the photolithography mask (die-to-die), it is advantageous to also stabilize the noise distribution in the reference image by applying the same transformation to the reference image as to the image. In case the reference image is an acquired image using a different optical system or different imaging conditions, it is also beneficial to stabilize the noise distribution in the reference image by applying a transformation to the reference image that reduces the variation of the noise distribution in the reference image. In this way, the registration is based on an image and a reference image with a more homogeneous noise distribution, which improves the accuracy of the registration results.

The structures in the image of the photolithography mask and the corresponding structures in the reference image of the photolithography mask can be registered using standard registration techniques, e.g., machine learning methods that map an image and a reference image to a displacement field, energy optimization methods that find a transformation of the image that minimizes the deviation between the transformed image and the reference image and, optionally, regularization terms, optical flow techniques, Random Sample Consensus (RANSAC) techniques, feature matching methods (e.g., SIFT features, Garbor features, features derived from layers of trained neural networks, etc.), the fast image alignment methods disclosed in German patent application 10 2024 139 922.8 that is hereby incorporated by reference in its entirety, etc.

Such registration methods, however, are usually implicitly based on the assumption of identically distributed noise in the image, in particular identically distributed Gaussian noise. This is due to the fact that registration methods usually do not take into account varying noise distributions in the image. Most registration methods even assume identically distributed Gaussian noise in the image. This is due to the fact that the minimization of an L₂-norm of the difference between the registered images or the maximization of a cross-correlation of the difference between registered images corresponds to the maximum likelihood estimator in case of identically distributed Gaussian noise. However, in case of optical images shot noise is the predominant source of noise in the image. Shot noise is illustrated in FIGS. 3A and 3B. In FIG. 3A, an image 22 acquired by an optical system comprising shot noise is shown. In FIG. 3B a difference image 24 of two images acquired by the optical system is shown, which is an estimate of the noise in the acquired image 22. In case of lower intensities, the noise variance is lower, whereas in case of higher intensities the noise variance is higher. Thus, shot noise depends on the image intensity. As shot noise is the predominant source of noise in the image 22, the assumption of identically distributed noise, let alone identically distributed Gaussian noise, does not hold, which reduces the accuracy of the registration.

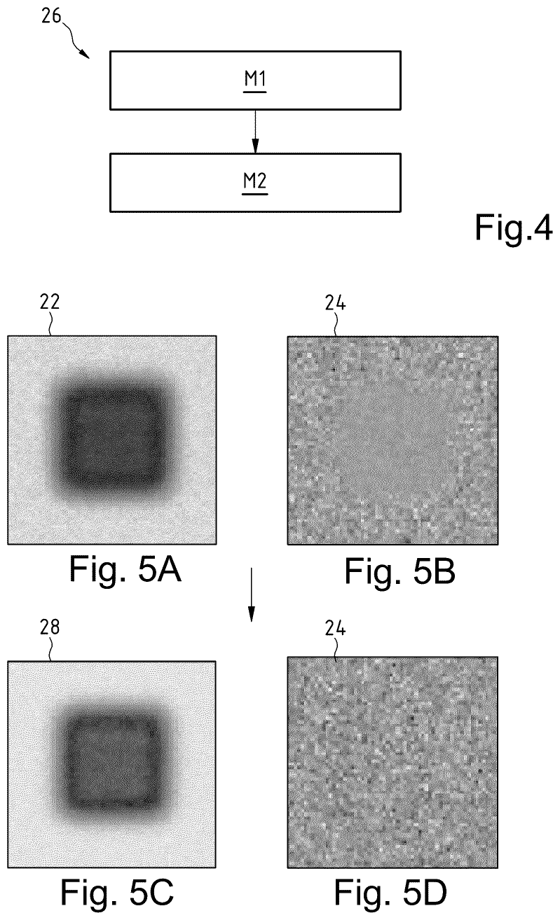

Therefore, according to an embodiment of the invention illustrated in FIG. 4, a method 26 for registering structures an image of a photolithography mask comprises: providing an image of a photolithography mask acquired by an optical system, wherein the image noise distribution varies depending on a property of the image, the photolithography mask or the optical system in a step M1; registering structures in a transformation of the image to corresponding structures in a reference image of the photolithography mask, wherein the variation of the noise distribution is reduced in the transformed image in a step M2.

As illustrated in FIGS. 5A-5D, by reducing the variation of the noise distribution in the transformed image, the noise in the image becomes closer to identically distributed noise and, thus, less dependent on the at least one property of the image, the photolithography mask or optical system. The noise distribution becomes more homogeneous over the image. The variance of the noise distribution becomes independent of the mean of the noise distribution. FIG. 5A shows the image 22 comprising image intensity dependent shot noise. FIG. 5B shows a difference image 24 of two different acquired images and, thus, an estimate of the noise distribution in the image 22. FIG. 5C shows a transformed image 28 with a reduced variation of the noise distribution, in particular a reduced variation of the variance of the noise distribution. FIG. 5D shows a difference image of two transformed images 28 and, thus, an estimate of the noise distribution in the transformed image 28. Here, the variation of the noise distribution is clearly reduced. In fact, the variance of the noise distribution is approximately constant in the transformed image 28 as illustrated in FIG. 5D and, thus close to independent from the at least one property of the image, the photolithography mask or the optical system. Thus, the assumptions of the registration methods are better fulfilled in the transformed image 28 than in the acquired image 22. In this way, the registration accuracy is improved.

In case of shot noise, the noise distribution in the image depends on the image intensity. Thus, the noise can be modeled by a Poisson distribution, where the variance of the distribution depends on its mean. Lower image intensities lead to noise of a lower variance, higher image intensities to noise of a higher variance. By transforming the image to a transformed image with a modified noise distribution, whose variance depends less on the image intensity, a more stable noise distribution can be obtained in the transformed image that better fulfills the assumptions of the registration methods.

The noise distribution in the image can contain a Poisson distributed component. The noise distribution in the image can also contain a Gaussian distributed component. Further noise components can also be contained in the noise distribution of the image. In a preferred example, the noise distribution contains two or more components that follow different distributions, e.g., a

Poisson distributed component and a Gaussian distributed component.

Apart from image intensity, the noise distribution in the image can vary depending on other properties of the image, the photolithography mask or the optical system. The noise distribution can, for example, vary depending on the location of the image. For example, the noise distribution in the center of the image can be different from the noise distribution on the edges of the image, e.g., the variance of the noise can be lower in the center of the image than on the edges of the images due to a different contrast or focus. The noise distribution can, for example, vary depending on the image contents, e.g., depending on the type of structures in the image. The noise distribution can vary depending on the material of structures on the photolithography mask, e.g., depending on their reflection coefficients. The noise distribution can vary depending on optical system components, e.g., on the different detectors or their properties, on camera sensors or pixels, in particular on degraded or defect optical system components such as defect detectors, camera sensors or pixels. For example, one or more detectors, camera sensors or pixels can be degraded or defect and generate subimages or image signals with different noise distributions. This problem can be alleviated by reducing the variation of the noise distribution in the image by a transformation.

Various transformations can be used to reduce the variation of the noise distribution in the image.

In a preferred example, the transformation of the image comprises a variance stabilizing transformation. A variance stabilizing transformation reduces the variability of the variance of the noise distribution in an image. After applying the variance stabilizing transformation to the image, the variance of the noise distribution in the image is closer to constant variance. The variability of the variance of the noise distribution can, for example, be measured by the variance of the variance of the noise distribution in the image. In a particular case, a variance stabilizing transformation transforms an image with a Poisson noise distribution, whose variance depends on at least one property of the image, the photolithography mask or the optical system, to a transformed image with an approximately identically distributed Gaussian noise distribution.

The aim behind the choice of a variance-stabilizing transformation is to apply a function to an image such that the variance of the values in the transformed image depend less on the property of the image, the photolithography mask or the optical system, e.g., less on the image intensities. For example, assuming that values x are realizations from different Poisson distributions (e.g., for low and high image intensities). Then the distributions have different mean values. As for the Poisson distribution the variance is identical to the mean, the variance varies with the mean of the noise distribution, i.e., with the image intensity. However, if the variance-stabilizing transformation f(x)=\sqrt{(x)} is applied, the variance of the noise distribution of the transformed image will be nearly constant and, thus, better fulfill the assumptions of the registration methods.

In an example, the variance stabilizing transformation comprises an Anscombe transform. The Anscombe transform is a variance-stabilizing transformation that transforms a random variable with a Poisson distribution into one with an approximately standard Gaussian distribution. The Anscombe transform for a random variable x is given by:

$$f ( x ) = 2 \sqrt{x + \frac{3}{8}}$$

In an example, the variance stabilizing transformation comprises a generalized Anscombe transform. The generalized Anscombe transform is a variance-stabilizing transformation that transforms a random variable with a Poisson distribution component and an additive Gaussian component into one with an approximately standard Gaussian distribution. Let N noisy pixel intensities of an image be described using random variables

$${x}_{i} = α {p}_{i} + {n}_{i} , i = 1 , … , N$$

where α refers to a scaling factor, pᵢ refers to independent random Poisson variables and nᵢ refers to an independent Gaussian noise component with mean μ and variance σ. Then the generalized Anscombe transform for the random variable x is given by:

$$f ( x ) = \frac{2}{α} \sqrt{α x + \frac{3}{8} {α}^{2} + {σ}^{2} - αμ} .$$

The parameters of the noise distribution in the image and, thus, the parameters of the generalized Anscombe transform are often not known a priori or change over time, e.g., due to degrading sensors of the optical system or due to different normalization steps in the software, etc.

Therefore, it is beneficial to estimate these parameters from one or more acquired images of the optical system. The parameter α is a real number and may be selected as a positive gain parameter, for example in a range from about 10⁻² to about 10², preferably in a range from 10⁻² to 10.

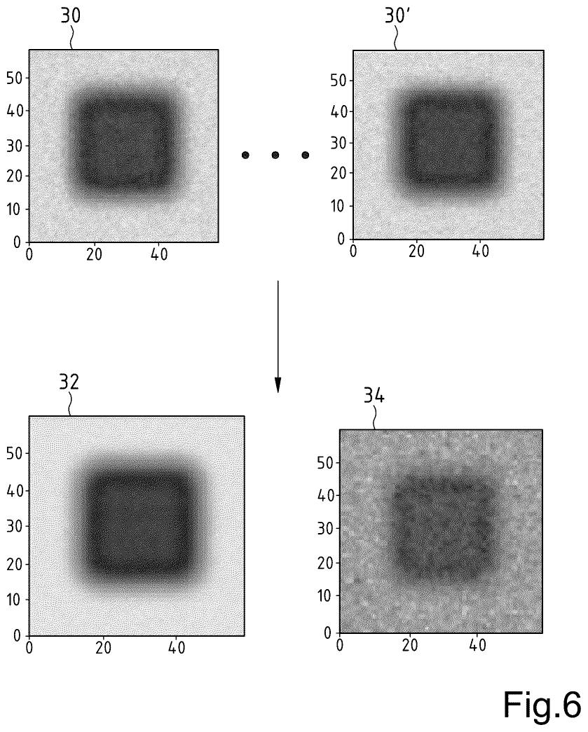

In case the parameters of the noise distribution of the image are estimated from a single image of the optical system, certain assumptions on the measured structure and/or on the optical system have to be made to able to differentiate between signal and noise impact. For example, the parameters can be estimated from homogeneous regions in the image. To obtain an improved accuracy, the parameters can be estimated from two or more, preferably multiple, images of the same photolithography mask acquired by the optical system as illustrated in FIG. 6. There, multiple images 30 of the same die of the photolithography mask are acquired. From these images 30, the parameters of the generalized Anscombe transform are estimated, for example, the pixel mean 32 and standard deviation 34 of the Gaussian noise distribution component.

Instead of or in addition to estimating parameters of the noise distribution of the image from one or more acquired images of the optical system, parameters of the noise distribution of the image can also be estimated from the optical system. In a particular example, the estimate of the expected number of photons and, hence, the related shot noise model, can also involve measurement information from an energy monitor in a system where images are acquired using pulsed illumination.

The transformed image in FIG. 5C is obtained by applying the generalized Anscombe transform as variance stabilizing transformation to the image in FIG. 5A, yielding a nearly Gaussian noise distribution illustrated in FIG. 5D. The parameters were estimated from multiple acquired images.

According to an example, the variance stabilizing transformation is obtained by solving an optimization problem that minimizes the deviation of an estimated noise variance in the image from a constant noise variance. Let q indicate a vector of parameters of the variance stabilizing transformation, e.g., of the Anscombe or generalized Anscombe transform. Then the parameters q could be estimated from one or more images by minimizing the following objective function

$$q = arg min {\vert {Var}_{est} [ {f}_{q} ( {x}_{i} ) ] - c \vert}_{2}$$

where Varₑₛₜ refers to an estimator of the pixelwise variance (e.g., the standard Monte Carlo estimators of the variance for multiple acquired images of a photolithography mask comprising, for example, well-defined mask features such as alignment markers, blank parts or big absorber structures), f_{q} refers to a parameterized variance stabilizing transformation with parameters q, xᵢ refers to N noisy pixel intensities of one or more images as described above, and c refers to a constant, e.g., c=1. By solving the optimization problem, the variance of the noise distribution in the transformed image becomes close to the constant c.

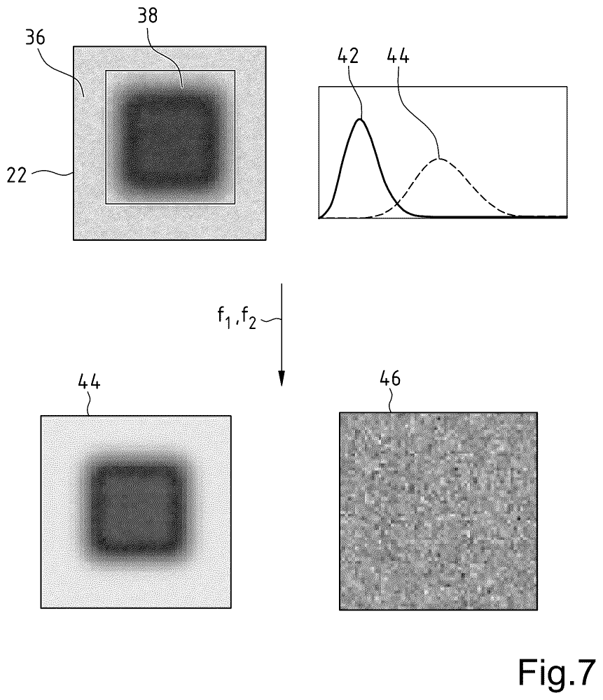

In an example illustrated in FIG. 7, the image 22 comprises at least two subimages 36, 38, each with a different noise distribution 40, 42, and the variation of the noise distribution is reduced within each subimage 36, 38 of the image 22. The noise in the first subimage 36 is distributed according to the first noise distribution. The noise in the second subimage 38 is distributed according to the second noise distribution 42. A first transformation f₁ can be applied to the first subimage 36 to obtain a noise distribution with lower variation. A second transformation f₂ can be applied to the second subimage 38 to obtain a noise distribution with lower variation. The transformations f₁ and f₂ can be different and, thus, adapted to the noise distribution in each subimage 36, 38. The resulting transformed image has a mean 44 and a standard deviation 46, wherein the standard deviation is independent of the mean. The noise distribution is more homogeneous and depends less on properties of the image, the photolithography mask or the optical system. By reducing the variation of the noise distribution within each subimage separately, the transformations can be exactly tailored to each subimage. This procedure may, for example, be beneficial in case of single degraded sensors, or by assigning each portion of the image obtained by a different sensor to a different subimage. This allows for even more accurate registration results.

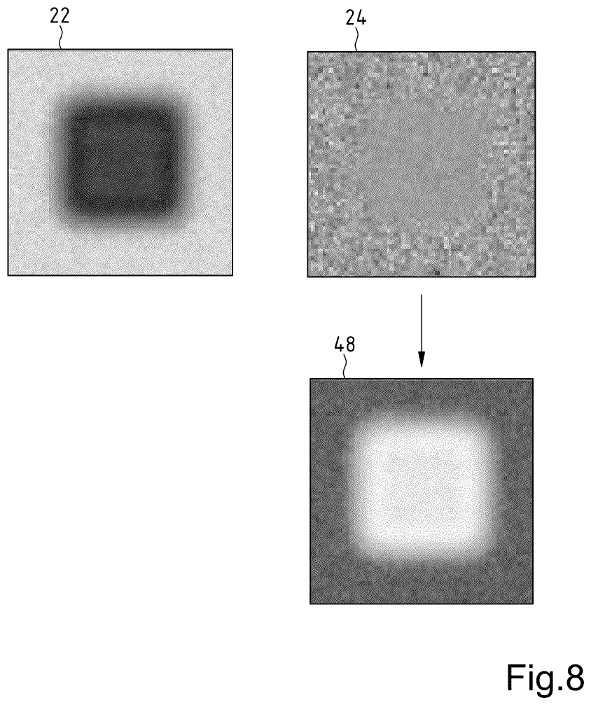

According to an example illustrated in FIG. 8, a pixelwise confidence score is estimated from the noise distribution of the image, and the confidence score is used as a weighting factor when registering structures in the transformed image to corresponding structures in the reference image. The image 22 is shown with a corresponding noise distribution estimate in the form of a difference image 24 of two acquired images of the optical system. The inverse of the variance of the noise distribution is used as confidence score 48. The higher the variance of the noise distribution the lower the confidence score 48 and vice versa. Portions of the image 22 with low noise variance are more reliable than portions of the image 22 with high noise variance and, thus, are weighted higher in the registration method. The weighting factor can, for example, be used for weighting each pixel in a difference between the image and a shifted reference image. Such a difference is optimized by many registration methods, e.g., in energy optimization methods. In this way, the accuracy of the registration is improved.

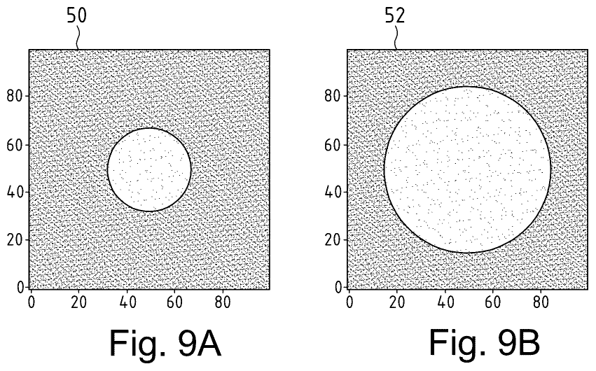

According to an example illustrated in FIGS. 9A and 9B, the transformation of the image further comprises filtering the image using a filter 52 that depends on the shape of an imaging pupil 50 of the optical system. The imaging pupil 50 in FIG. 9A indicates the range of spatial frequencies of the electric field that pass through the projection optics of the optical system. These spatial frequencies form a circle (left). The image sensor measures the intensity of the electric field, which can contain spatial frequencies up to twice the maximum frequency of the electric field (circle on the right with twice the radius of the circle on the left). Thus, the optical system acts as a respective low-pass filter. High frequency components in the image above the maximum frequency of the filter 52 must be due to noise in the image and can be filtered by the filter 52 in FIG. 9B. This filter will be called NA-filter in the following. By filtering these noise frequencies from the image, the noise in the image is reduced and the quality of the registration increased. The shape of the imaging pupil is not limited to a circle, it can take other shapes as well from which corresponding NA filters can be derived.

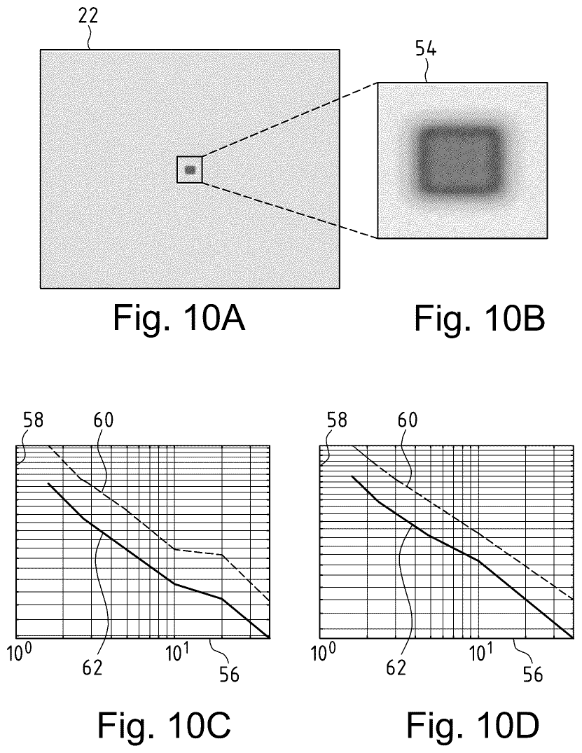

FIGS. 10A-10D show results concerning the reproducibility of the method according to the invention. FIG. 10A shows an image acquired by an optical system, and FIG. 10B shows a subsection 54 containing a 500 nm isolated contact structure of the photolithography mask. The registration of this image to the reference image is affected by noise in the image. FIGS. 10C and 10D show reproducibility tests for registration measurements, FIG. 10C for horizontal displacements, FIG. 10D for vertical displacements. The registration is carried out for different laser intensities on the horizontal axis, for each laser intensity the registration is repeated 20 times for repeatedly acquired images of the optical system. The horizontal axis 56 shows the increasing laser intensity, the vertical axis 58 the standard deviation of the displacement measurements in horizontal (FIG. 10C), respectively, vertical direction (FIG. 10D). The first graph 60 shows reproducibility results for the raw image, the second graph 62 for a generalized Anscombe transformed image. With increasing laser intensity the number of photons incident on the photolithography mask increases and, thus, the image noise is reduced as shown by the graphs 60, 62. From the graphs 60, 62 it can be concluded that the reproducibility of the measurements is improved by approximately 20% for a fixed laser intensity if the image is transformed to reduce the variability of the noise distribution in the image before the registration. At the same time it can be concluded that the same reproducibility of the registration can be achieved using an approximately 50% reduced laser intensity, if the image is transformed to reduce the variability of the noise distribution in the image before the registration. By reducing the laser intensity, damages to the photolithography mask can be reduced or prevented.

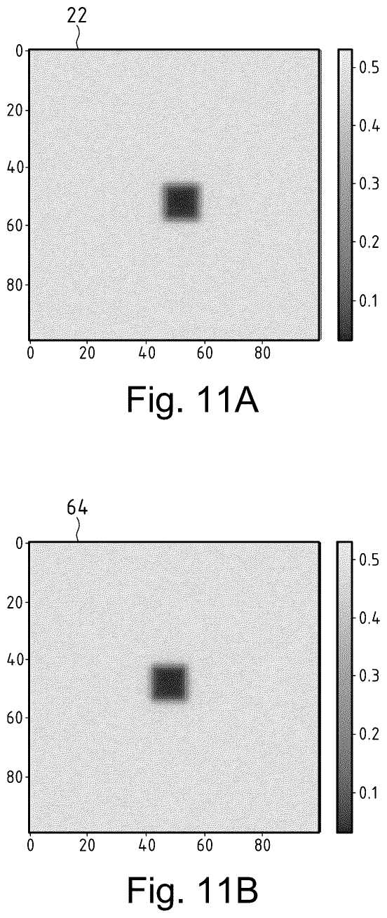

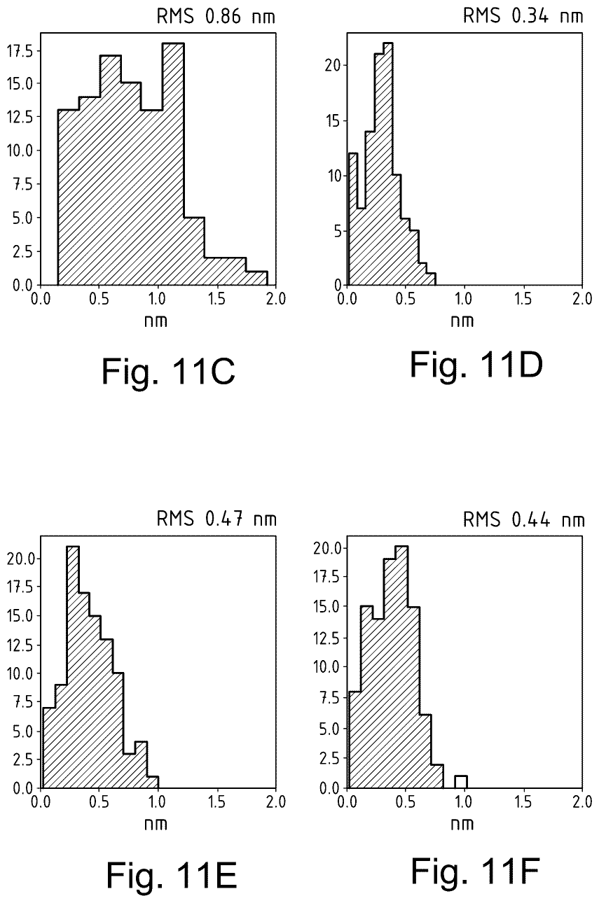

FIGS. 11A-11F show registration error distributions for different preprocessing methods of the image. FIGS. 11A and 11B show a simulated image 22 and a simulated reference image 64 comprising 100×100 pixels, each pixel corresponding to a size of 25 nm×25 nm on the photolithography mask. Both images are simulated for a photolithography mask comprising a quadratic absorber of size 300 nm in the center of the field of view with different shifts of the absorber drawn from a uniform distribution over the interval [−50 nm, 50 nm]. Monochromatic illumination with wavelength of 100 nm is used in the simulation, and a partially coherent imaging simulation for a conventional illumination setting with circular illumination and imaging pupils with a numerical aperture of 0.7 as shown in FIG. 9A. Both images comprise random shot noise realizations, assuming a mean value of 2000 photons on bright pixels. The registration of the images is carried out by minimizing the L₂-norm of the difference image. The registration error measures the Euclidean norm of the difference between the estimated shift by the registration and the known true shift. FIGS. 11C-11F show distributions over the registration error for different preprocessing methods: no preprocessing (FIG. 11C) leading to a root mean squared error of 0.86 nm, Anscombe transform in combination with subsequent NA filter (FIG. 11D) leading to a root mean squared error of 0.34 nm, Anscombe transform only (FIG. 11E) leading to a root mean squared error of 0.47 nm, and NA filter only (FIG. 11F) leading to a root mean squared error of 0.44 nm. This demonstrates that using image transforms to reduce the variability of the noise distribution in the image such as the Anscombe transform as well the use of the NA filter that depends on the shape of the imaging pupil of the optical system strongly increase the registration accuracy. The registration accuracy is increased the most if both, the Anscombe transform and the NA filter, are used in combination.

Concerning the order of application of the Anscombe transform and the NA filter, the Anscombe transform can be applied before the NA filter as shown in FIG. 11D. However, this is theoretically not optimal, as the Anscombe transform is non-linear and affects the spectrum of the image, such that the subsequent application of the NA filter will not exclusively remove noise frequencies from the image but also frequencies comprising image signal. Nevertheless, this combination of Anscombe transform and subsequent NA filter yields the lowest registration errors. Applying the Anscombe transform after the NA filter is theoretically not optimal, either, since the noise in the low-pass filtered image does not follow a Poisson distribution anymore. In order to alleviate this problem, parameters a=(a₁, a₂) of a general image transformation

$${T}_{a} ( x ) = {a}_{1} sgn ( x + {a}_{2} ) \sqrt{( \vert x + {a}_{2} \vert )}$$

could be derived, such that this image transformation would be particularly tailored to the NA filtered image. The parameters a₁ and a₂ are real numbers. They may be selected, for example, by a₁>0, and a₂ may be selected such that the transformation Tₐ(x) is numerically stable over the dynamic range of the filtered image, wherein a₂ is selected within the range of expected pixel values (e.g., within approximately ±Xₘₐₓ, where Xₘₐₓ is the maximum absolute intensity in the image).

According to an example, the method further comprises evaluating the quality of the photolithography mask from registered structures in the image and the reference image.

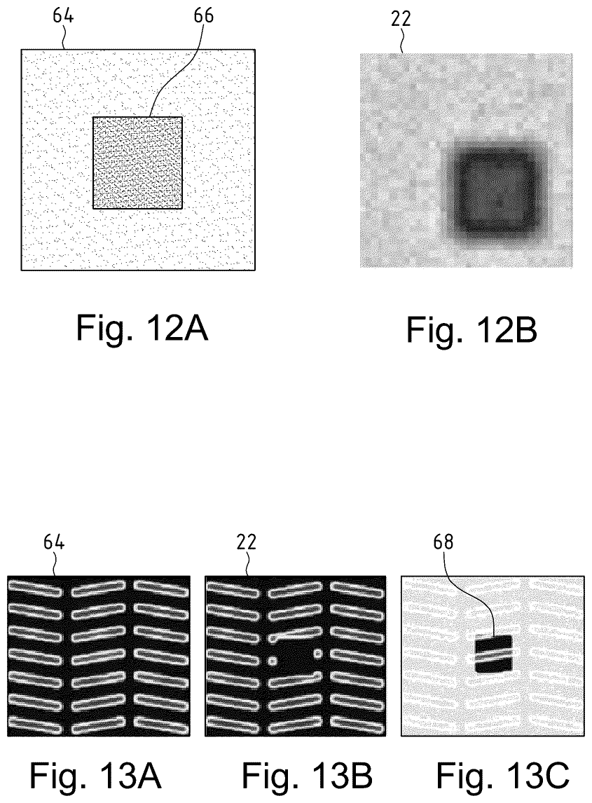

The quality of the photolithography mask can be evaluated by determining positional deviations of structures on the photolithography mask as illustrated in FIGS. 12A and 12B. FIG. 12A shows a reference image 64, e.g., a design file, comprising a structure 66 and FIG. 12B a measured image 22 of the photolithography mask comprising shot noise. Provided the position of the structure 66 in the reference image 64 is known, its absolute position on the photolithography mask can be derived from the registration information, i.e., from the relative displacement of the structure in the image 22 from the corresponding structure in the reference image. In case the absolute position on the photolithography mask is not known, a relative displacement between the registered structures can be computed. In this way, quality statements can be made about the photolithography mask, e.g., about an average or a maximum deviation of a position of a structure from a reference position, or about a statistic of position deviations. In addition, accurate overlays between consecutive layers of the photolithography mask can be verified, e.g., for structures that traverse consecutive layers. Thresholds can be defined, and in case a threshold is exceeded, the photolithography mask can be repaired or discarded.

The quality of the photolithography mask can also be evaluated by detecting defects 68 in the photolithography mask as illustrated in FIGS. 13A-13C, e.g., by detecting structures in the image 22 (FIG. 13B) that deviate from corresponding structures in the reference image 64 (FIG. 13A). After reducing the variation of the noise distribution in the image (and potentially in the reference image) the transformed image and the reference image are registered with an increased accuracy. Then defects are detected from the registered transformed image and reference image or, alternatively, from the registered image and the reference image without transformation. To this end, the registration error, i.e., the deviation of the structures in the image and the reference image after registration can be used, e.g., by computing a difference image and thresholding the difference, or by applying a trained machine learning model that uses the registered image and reference image as input that is mapped to defect indicators, e.g., an image with a defect likelihood. Alternatively, the remaining local energy, objective function value or loss function value after registration, can be used as registration error. Local structures that lead to a high registration error indicate a defect in the structures of the photolithography mask, since, usually, there are no corresponding structures in the reference image. In order to locate the outline of a defect 68, a segmentation of the registration error can, for example, be computed using image processing methods. The segmented defects 68 can be measured. In addition, the defects can be classified, e.g., by using a trained machine learning model. Depending on properties of the defects (e.g., their size, location, type, relevance, etc.) a defect can be reduced, repaired or ignored, or the whole photolithography mask can be discarded. In this way, quality statements can be made about the photolithography mask, e.g., about the number of defects per area, the total number of defects, the type of defects, the severity of defects, measurements of defects, etc. Thresholds can be defined, and in case a threshold is exceeded, the photolithography mask can be repaired or discarded.

In an example, the method further comprises controlling at least one photolithography mask manufacturing process parameter (e.g., a focus, exposure, etc.) based on the quality evaluation of the photolithography mask (e.g., based on the measured positions of the structures in the photolithography mask in case of an optical metrology system or based on the detected defects in the photolithography mask in case of an optical inspection system).

In some implementations, after defects are detected, the photolithography mask can be modified to repair or eliminate the defects. Repairing the defects can include, e.g., depositing materials on the mask using a deposition process, removing materials from the mask using an etching process, or locally modifying a property of the object. This can, for example, comprise locally modifying at least one of a density, a refractive index, a transparency, or a reflectivity of the photolithography mask.

In some implementations, the information about the defects serve as feedback to improve the process parameters of the manufacturing process, e.g., exposure time, focus, etc. For example, after the defects are identified from a first photolithography mask or first batch of photolithography masks, the process parameters of the manufacturing process are adjusted to reduce defects in a second mask or a second batch of masks.

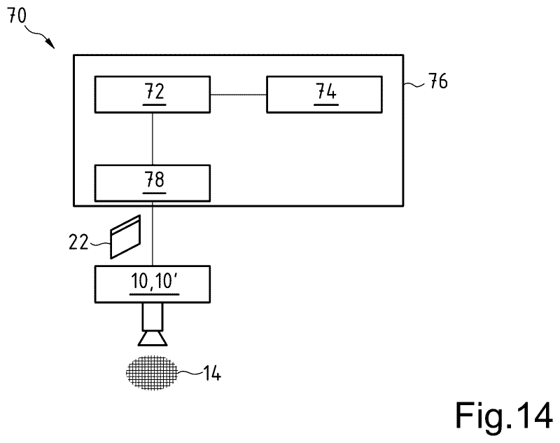

A system 70 for registering structures in an image of a photolithography mask 14 obtained by an optical system 10, 10′ according to an embodiment of the invention illustrated in FIG. 14 comprises: an optical system 10, 10′ for acquiring an image of a photolithography mask as illustrated in FIGS. 1 and 2; one or more processing devices 72; one or more machine-readable hardware storage devices 74 comprising instructions that are executable by one or more processing devices 72 to perform operations comprising a method for registering structures in an image of a photolithography mask as described in any of the embodiments, examples or aspects above.

The system 70 optionally comprises a database for loading and/or saving data, e.g., noise distributions, image transformations, defect detection method control parameters, reference images, defect properties, etc. The optical system 10, 10′ is used for obtaining an image 22 of the photolithography mask 14. It can provide the image 22 to the data analysis device 76. The data analysis device 76 includes one or more processors 72, e.g., implemented as a central processing unit (CPU) or graphics processing unit (GPU). The one or more processors 72 can receive the at least one image via an interface 78. The one or more processors 72 can load program code from a hardware-storage device 74, e.g., program code for executing a computer implemented method 26 for registering structures in an image of a photolithography mask as described above.

The one or more processors 72 can execute the program code. The system 70 optionally comprises a user interface, e.g., for entering noise distributions or parameters thereof, image transformations or parameters thereof, etc.

Reference throughout this specification to “an embodiment” or “an example” or “an aspect” means that a particular feature, structure or characteristic described in connection with the embodiment, example or aspect is included in at least one embodiment, example or aspect. Thus, appearances of the phrases “according to an embodiment”, “according to an example” or “according to an aspect” in various places throughout this specification are not necessarily all referring to the same embodiment, example or aspect, but may refer to different embodiments, examples, or aspects. Furthermore, the particular features or characteristics may be combined in any suitable manner, as would be apparent to one of ordinary skill in the art from this disclosure, in one or more embodiments.

In some implementations, each of the one or more processing devices can include one or more processor cores, and each processor core can include logic circuitry for processing data. For example, a processor can include an arithmetic and logic unit (ALU), a control unit, and various registers. Each processor can include cache memory. Each processor can include a system-on-chip (SoC) that includes multiple processor cores, random access memory, graphics processing units, one or more controllers, and one or more communication modules. Each processor can include millions or billions of transistors.

In some implementations, the one or more processing devices can include one or more computers, each computer can include one or more data processors for processing data. The one or more machine-readable hardware storage devices can store one or more computer programs including instructions that when executed by the one or more computers cause the one or more computers to carry out the processes described above. The one or more processing devices can include one or more input devices, such as a keyboard, a mouse, a touchpad, and/or a voice command input module, and one or more output devices, such as a display, and/or an audio speaker.

In some implementations, the one or more processing devices can include digital electronic circuitry, computer hardware, firmware, software, or any combination of the above. The features related to processing of data can be implemented in a computer program product tangibly embodied in an information carrier, e.g., in a machine-readable storage device, for execution by a programmable processor; and method steps can be performed by a programmable processor executing a program of instructions to perform functions of the described implementations. Alternatively or in addition, the program instructions can be encoded on a propagated signal that is an artificially generated signal, e.g., a machine-generated electrical, optical, or electromagnetic signal, that is generated to encode information for transmission to suitable receiver apparatus for execution by a programmable processor.

A computer program can be written in any form of programming language, including compiled or interpreted languages, and it can be deployed in any form, including as a stand-alone program or as a module, component, subroutine, or other unit suitable for use in a computing environment.

For example, the one or more computers can be configured to be suitable for the execution of a computer program and can include, by way of example, both general and special purpose microprocessors, and any one or more processors of any kind of digital computer. Generally, a processor will receive instructions and data from a read-only storage area or a random access storage area or both. Elements of a computer system include one or more processors for executing instructions and one or more storage area devices for storing instructions and data. Generally, a computer system will also include, or be operatively coupled to receive data from, or transfer data to, or both, one or more machine-readable storage media, such as hard drives, magnetic disks, solid state drives, magneto-optical disks, or optical disks. Machine-readable storage media suitable for embodying computer program instructions and data include various forms of non-volatile storage area, including by way of example, semiconductor storage devices, e.g., EPROM, EEPROM, flash storage devices, and solid state drives; magnetic disks, e.g., internal hard disks or removable disks; magneto-optical disks; and CD-ROM, DVD-ROM, and/or Blu-ray discs.

In some implementations, the processes described above can be implemented using software for execution on one or more mobile computing devices, one or more local computing devices, and/or one or more remote computing devices (which can be, e.g., cloud computing devices). For instance, the software forms procedures in one or more computer programs that execute on one or more programmed or programmable computer systems, either in the mobile computing devices, local computing devices, or remote computing systems (which may be of various architectures such as distributed, client/server, grid, or cloud), each including at least one processor, at least one data storage system (including volatile and non-volatile memory and/or storage elements), at least one wired or wireless input device or port, and at least one wired or wireless output device or port.

In some implementations, the software may be provided on a medium, such as CD-ROM, DVD-ROM, Blu-ray disc, a solid state drive, or a hard drive, readable by a general or special purpose programmable computer or delivered (encoded in a propagated signal) over a network to the computer where it is executed. The functions can be performed on a special purpose computer, or using special-purpose hardware, such as coprocessors. The software can be implemented in a distributed manner in which different parts of the computation specified by the software are performed by different computers. Each such computer program is preferably stored on or downloaded to a storage media or device (e.g., solid state memory or media, or magnetic or optical media) readable by a general or special purpose programmable computer, for configuring and operating the computer when the storage media or device is read by the computer system to perform the procedures described herein. The inventive system can also be considered to be implemented as a computer-readable storage medium, configured with a computer program, where the storage medium so configured causes a computer system to operate in a specific and predefined manner to perform the functions described herein.

Furthermore, while some embodiments, examples or aspects described herein include some but not other features included in other embodiments, examples or aspects combinations of features of different embodiments, examples or aspects are meant to be within the scope of the claims, and form different embodiments, as would be understood by those skilled in the art.

Embodiments, examples and aspects of the invention can be described by the following clauses:
1. A method 26 for registering structures in an image 22 of a photolithography mask 14, the method comprising:
   Providing an image 22 of a photolithography mask 14 acquired by an optical system 10, 10′, wherein the noise distribution of the image 22 varies depending on at least one property of the image 22, the photolithography mask 14 or the optical system 10, 10′;
   Registering structures in a transformation of the image 22 to corresponding structures in a reference image 64 of the photolithography mask 14, wherein the variation of the noise distribution is reduced in the transformed image 28.
2. The method of clause 1, wherein the noise distribution of the image 22 comprises a Poisson distributed component.
3. The method of any one of the preceding clauses, wherein the noise distribution of the image 22 comprises a Gaussian distributed component.
4. The method of any one of the preceding clauses, wherein the noise distribution of the image 22 varies depending on at least one property of the image 22, the photolithography mask 14 or the optical system 10, 10′ from the group comprising: image intensity, image location, image contents, photolithography mask material, photolithography mask structure type, detector properties of the optical system.
5. The method of any one of the preceding clauses, wherein the variance of the noise distribution of the image 22 varies depending on the at least one property of the image, and wherein the variation of the variance of the noise distribution is reduced in the transformed image 28.
6. The method of any one of the preceding clauses, wherein the variance of the noise distribution of the transformed image 28 is approximately constant.
7. The method of any one of the preceding clauses, wherein the noise distribution of the transformed image 28 approximately follows an identically distributed Gaussian distribution.
8. The method of any one of the preceding clauses, wherein the transformation of the image 22 comprises a variance stabilizing transformation.
9. The method of clause 8, wherein the variance stabilizing transformation comprises an Anscombe transform.
10. The method of clause 8 or 9, wherein the variance stabilizing transformation comprises a generalized Anscombe transform.
11. The method of any one of clauses 8 to 10, wherein the variance stabilizing transformation is obtained by solving an optimization problem that minimizes the deviation of an estimated noise variance in the image from a constant noise variance.
12. The method of any one of the preceding clauses, wherein the image 22 comprises at least two subimages 36, 38, each with a different noise distribution 40, 42, and wherein the variation of the noise distribution is reduced within each subimage 36, 38 of the image 22.
13. The method of any one of the preceding clauses, wherein a pixelwise confidence score 48 is estimated from the noise distribution of the image 22, and wherein the confidence score 48 is used as a weighting factor when registering structures in the transformed image 28 to corresponding structures in the reference image 64.
14. The method of any one of the preceding clauses, wherein parameters of the noise distribution of the image 22 are estimated from one or more images 30, 30′ obtained by the optical system 10, 10′.
15. The method of any one of the preceding clauses, wherein parameters of the noise distribution of the image 22 are estimated from the optical system 10, 10′.
16. The method of any one of the preceding clauses, wherein the transformation of the image 22 further comprises filtering the image using a filter 52 that depends on the shape of an imaging pupil 50 of the optical system 10, 10′.
17. The method of any one of the preceding clauses, wherein a transformation is applied to the reference image that reduces the variation of the noise distribution in the reference image.
18. The method of any one of the preceding clauses, further comprising evaluating the quality of the photolithography mask 14 from registered structures 66 in the image 22 and the reference image 64.
19. The method of any one of the preceding clauses, wherein the optical system 10, 10′ is an optical metrology system that measures positions of structures 66 in the photolithography mask 14 from registered structures in the image 22 and the reference image 64.
20. The method of any one of the preceding clauses, wherein the optical system 10, 10′ is an optical inspection system that detects defects 68 in the photolithography mask 14 by comparing registered structures 66 in the image 22 and the reference image 64.
21. The method of any one of clauses 18 to 20, further comprising controlling at least one photolithography mask manufacturing process parameter based on the quality evaluation of the photolithography mask.
22. A system 70 for registering structures in an image 22 of a photolithography mask 14 obtained by an optical system 20, 10′, the system comprising:
   An optical system 10, 10′ for acquiring an image 22 of a photolithography mask 14;
   One or more processing devices 72;
   One or more machine-readable hardware storage devices 74 comprising instructions that are executable by one or more processing devices 72 to perform operations comprising a method 26 for registering structures in an image 22 of a photolithography mask 14 according to any one of the preceding clauses.

In a general aspect, a method 26 for registering structures in an image 22 of a photolithography mask 14 comprises: providing an image 22 of a photolithography mask 14 acquired by an optical system 10, 10′, wherein the noise distribution of the image 22 varies depending on at least one property of the image 22, the photolithography mask 14 or the optical system 10, 10′; and registering structures in a transformation of the image 22 to corresponding structures in a reference image 64 of the photolithography mask 14, wherein the variation of the noise distribution is reduced in the transformed image 28.

### REFERENCE NUMBER LIST

10, 10′ Optical metrology system
12 Light source
14 Photolithography mask
16 Illumination optics
17 Projection optics
18 Wafer plane
19 Projection section
20 Image sensor
22 Image
24 Difference image
26 Method
28 Transformed image
30, 30′ Image
32 Mean
34 Standard deviation
36 First subimage
38 Second subimage
40 First noise distribution
42 Second noise distribution
44 Mean
46 Standard deviation
48 Confidence score
50 Imaging pupil
52 Filter
54 Subsection
56 Horizontal axis
58 Vertical axis
60 First graph
62 Second graph
64 Reference image
66 Structure
68 Defect
70 System
72 Processing device
74 Machine-readable hardware storage device
76 Data analysis device
78 Interface

What is claimed is:

1. A method for registering structures in an image of a photolithography mask, the method comprising:
providing an image of a photolithography mask acquired by an optical system, wherein the noise distribution of the image varies depending on at least one property of the image, the photolithography mask or the optical system; and
registering structures in a transformation of the image to corresponding structures in a reference image of the photolithography mask, wherein the variation of the noise distribution is reduced in the transformed image.

2. The method of claim 1, wherein the noise distribution of the image comprises a Poisson distributed component.

3. The method of claim 2, wherein the noise distribution of the image comprises a Gaussian distributed component.

4. The method of claim 1, wherein the noise distribution of the image varies depending on at least one property of the image, the photolithography mask or the optical system from the group comprising: image intensity, image location, image contents, photolithography mask material, photolithography mask structure type, detector properties of the optical system.

5. The method of claim 1, wherein the variance of the noise distribution of the image varies depending on the at least one property of the image, and wherein the variation of the variance of the noise distribution is reduced in the transformed image.

6. The method of claim 1, wherein the variance of the noise distribution of the transformed image is approximately constant.

7. The method of claim 1, wherein the noise distribution of the transformed image approximately follows an identically distributed Gaussian distribution.

8. The method of claim 1, wherein the transformation of the image comprises a variance stabilizing transformation.

9. The method of claim 8, wherein the variance stabilizing transformation comprises an Anscombe transform.

10. The method of claim 8, wherein the variance stabilizing transformation comprises a generalized Anscombe transform.

11. The method of claim 8, wherein the variance stabilizing transformation is obtained by solving an optimization problem that minimizes the deviation of an estimated noise variance in the image from a constant noise variance.

12. The method of claim 1, wherein the image comprises at least two subimages, each with a different noise distribution, and wherein the variation of the noise distribution is reduced within each subimage of the image.

13. The method of claim 1, wherein a pixelwise confidence score is estimated from the noise distribution of the image, and wherein the confidence score is used as a weighting factor when registering structures in the transformed image to corresponding structures in the reference image.

14. The method of claim 1, wherein parameters of the noise distribution of the image are estimated from one or more images obtained by the optical system.

15. The method of claim 1, wherein parameters of the noise distribution of the image are estimated from two or more images obtained by the optical system.

16. The method of claim 1, wherein parameters of the noise distribution of the image are estimated from the optical system.

17. The method of claim 1, wherein the transformation of the image further comprises filtering the image using a filter that depends on the shape of an imaging pupil of the optical system.

18. The method of claim 17, wherein the transformation is a variance-stabilizing transformation that is specifically optimized to account for the modified noise distribution of the filtered image.

19. The method of claim 18, wherein the parameterized, non-linear transformation has the form Tₐ₍ₓ₎=a₁sgn(x+a₂)\sqrt{x+a₂|}.

20. The method of claim 1, wherein a transformation is applied to the reference image that reduces the variation of the noise distribution in the reference image.

21. The method of claim 1, further comprising evaluating the quality of the photolithography mask from registered structures in the image and the reference image.

22. The method of claim 1, wherein the optical system is an optical metrology system that measures positions of structures in the photolithography mask from registered structures in the image and the reference image.

23. The method of claim 1, wherein the optical system is an optical inspection system that detects defects in the photolithography mask by comparing registered structures in the image and the reference image.

24. The method of claim 21, further comprising controlling at least one photolithography mask manufacturing process parameter based on the quality evaluation of the photolithography mask.

25. A system for registering structures in an image of a photolithography mask obtained by an optical system, the system comprising:
an optical system for acquiring an image of a photolithography mask;
one or more processing devices; and
one or more machine-readable hardware storage devices comprising instructions that are executable by one or more processing devices to perform operations comprising a method for registering structures in an image of a photolithography mask according to claim 1.
